(19) United States
(12) Patent Application Publication
(10) Pub. No.: US 2021/0184653 A1
(43) Pub. Date: Jun. 17, 2021

(54) ACOUSTICALLY COUPLED RADIO FREQUENCY (RF) FILTER

(71) Applicant: University of Florida Research Foundation, Incorporated, Gainesville, FL (US)

(72) Inventor: Roozbeh Tabrizian, Gainesville, FL (US)

(21) Appl. No.: 17/117,977

(22) Filed: Dec. 10, 2020

Related U.S. Application Data
(60) Provisional application No. 62/947,011, filed on Dec. 12, 2019.

(51) Int. Cl. H03H 9/54; H03H 9/13; H03H 9/17; H03H 3/02

(52) U.S. Cl. CPC H03H 9/54; H03H 3/02; H03H 9/17; H03H 9/132

(57) ABSTRACT

An acoustically coupled RF filter system includes, in part, a first conductive layer, a ferroelectric layer, and a second conductive layer, wherein the second conductive layer includes a plurality of interdigital transducers (IDTs) formed thereon. The ferroelectric layer can be positioned above the first conductive layer, and there is a semi-trench formed in the ferroelectric layer. The second conductive layer can be positioned above the ferroelectric layer. The plurality of IDTs is formed by patterning the second conductive layer and forms an RF filter input and an RF filter output. The ferroelectric layer comprises Al₁₋ₓScₓN, wherein 0<x<1.

### CROSS-REFERENCE TO RELATED APPLICATIONS

This patent application claims priority to Provisional Application Ser. No. 62/947,011, filed Dec. 12, 2019, which is incorporated herein by reference in its entirety.

### TECHNICAL FIELD

The present application relates generally to the field of RF filters, and more specifically, to an acoustically coupled RF filter.

### BACKGROUND

The rapid evolution of wireless technology has improved the exchange of information globally. Due to extensive worldwide research and development, wireless technology has become more widely available and affordable. Consequently, the number of users of wireless technology scaled tremendously within two decades. The wireless communication market revolutionized with the first release of the smart phone. An exponential growth of services is occurring in a limited range of frequencies and therefore crowding the limited range significantly. However, high bandwidth is a very important requirement for the quality of specific operation. Communication channels need to be displaced by some unused frequencies to ensure zero interference. In order to efficiently use a particular spectrum, high selective filters must be employed. Acoustically coupled filters are amongst commercial candidates which have been under extensive research for several decades. Furthermore, low volume, low power, low cost, and good coupling are the main key drivers for acoustically coupled RF filters.

### SUMMARY

Disclosed is an acoustically coupled RF filter with large bandwidth reconfigurability. The acoustically coupled RF filter is realized in ferroelectric aluminum-scandium-nitride films. In some embodiments, the acoustically coupled RF filter system comprises a first conductive layer, a ferroelectric layer, and a second conductive layer comprising a plurality of interdigital transducers (IDTs).

In some embodiments, the ferroelectric layer is positioned above the first conductive layer. The ferroelectric layer may be sputtered over the first conductive layer. In some embodiments, a trench (or a semi-trench) is formed in the ferroelectric layer. The trench forms a trapezoid-shape region in the ferroelectric layer. In some embodiments, the first conductive layer is positioned above an insulation layer. In some embodiments, the trench extends fully through the ferroelectric layer. In some embodiments, the trench extends fully through the ferroelectric layer and partly into the first conductive layer. In some embodiments, the trench extends fully through the ferroelectric layer and the first conductive layer. In some embodiments, the trench extends fully through the ferroelectric layer and the first conductive layer, and partly into the insulation layer. In some embodiments, the trench extends fully through the stack of the ferroelectric layer, the first conductive layer, and the insulation layer. In some embodiments, an access to the first conductive layer is formed in the ferroelectric layer. Both the trench and the access to the first conductive layer may be formed in the ferroelectric layer by an etching technique. In some embodiments, the plurality of IDTs is formed by patterning the second conductive layer. The IDTs may comprise at least two sets of IDTs. Each set of IDTs may comprise about 10 IDT fingers. The IDTs may have a pitch of about 5 micrometers.

In some embodiments, the plurality of IDTs forms an input and an output for the acoustically coupled RF filter system. In some embodiments, the first conductive layer comprises a same material as the second conductive layer. In some embodiments, the first conductive layer and the second conductive layer comprise Molybdenum (Mo).

In some embodiments, the ferroelectric layer comprises aluminum-scandium-nitride (Al₁₋ₓScₓN) films. The Al₁₋ₓScₓN provides significantly higher electromechanical coupling compared to its aluminum-nitride (AlN) counterparts. Furthermore, Al₁₋ₓScₓN becomes ferroelectric when Sc-content (e.g., x) exceeds 27%. In some embodiments, the ferroelectric layer comprises Al₁₋ₓScₓN where x is about 0.27.

The large electromechanical coupling of the Al₁₋ₓScₓN film (x >0.27), leads to large bandwidths. In some embodiments, the Al₁₋ₓScₓN films are about 1 micrometer in thickness. In some embodiments, the aluminum scandium nitride films are engineered to implement 2.3 GHz filters with −3 dB bandwidths (e.g., BW−3 dB). In some embodiments, the −3 dB bandwidth is demonstrated over 70-117 MHz. In some embodiments, an insertion loss of −6 dB is observed. The observed insertion loss is dominated by a routing line resistance, in accordance with some embodiments. In some embodiments, bandwidth tuning of about 15 MHz (i.e., about 15% of the bandwidth) is achieved through application of a DC voltage of about 60 volts, using a bias-tee.

### BRIEF DESCRIPTION OF THE DRAWINGS

So that the present disclosure can be understood by those of ordinary skill in the art, a more detailed description can be had by reference to aspects of some illustrative embodiments, some of which are shown in the accompanying drawings.

FIGS. 1A-1I are different views of an exemplary acoustically coupled RF filter system, in accordance with some embodiments.

FIG. 1J is an expanded view of interdigital transducer (IDT) of an acoustically coupled RF filter, in accordance with another exemplary embodiments of the present invention.

FIG. 2A compares simulated results of different responses of an exemplary acoustically coupled RF filter with aluminum scandium nitride, in accordance with some embodiments, and an exemplary acoustically coupled RF filter with aluminum nitride.

FIG. 2B demonstrates measured filter response of an exemplary acoustically coupled RF filter system with aluminum scandium nitride, in accordance with some embodiments.

FIG. 3 illustrates a bandwidth tunability of an exemplary acoustically coupled RF filter system, through application of different DC voltages to an input IDT set, in accordance with some embodiments.

FIG. 4 illustrates a measured temperature coefficient of frequency (TCF) of an exemplary acoustically coupled filter system, in accordance with some embodiments.

FIG. 5 illustrates an exemplary method of fabricating an exemplary acoustically coupled RF filter, in accordance with some embodiments.

In accordance with common practice some features illustrated in the drawings cannot be drawn to scale. Accordingly, the dimensions of some features can be arbitrarily expanded or reduced for clarity. In addition, some of the drawings cannot depict all the components of a given system, method or device. Finally, like reference numerals can be used to denote like features throughout the specification and figures.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

Disclosed herein is an acoustically coupled filter system with large bandwidth reconfigurability, realized in ferroelectric aluminum-scandium-nitride films.

It will also be understood that, although the terms first, second, and/or the like are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact, unless the context clearly indicates otherwise.

The terminology used in the description of the various described embodiments herein is for the purpose of describing particular embodiments only and is not intended to be limiting. As used in the description of the various described embodiments and the appended claims, the singular forms “a,” “an,” and “the” are intended to comprise the plural forms as well, unless the context clearly indicates otherwise. It will also be understood that the term “and/or” as used herein refers to and encompasses any and all possible combinations of one or more of the associated listed items. It will be further understood that the terms “comprises,” “comprising,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

It should be appreciated that in the development of any actual implementation (as in any development project), numerous decisions must be made to achieve the developers' specific goals (e.g., compliance with system and business-related constraints), and that these goals will vary from one implementation to another. It will also be appreciated that such development efforts might be complex and time consuming but would nevertheless be a routine undertaking for those of ordinary skill in the art of image capture having the benefit of this disclosure.

Since the majority of acoustically coupled RF filters cannot be tuned, a hardware manufacturer is restricted to integrate big bank of filters into a single functional device. This is a vital functional requirement in order to ensure there is no interference among different channels. The existing solution requires high power and big space in the device in order to ensure a reliable functionality.

Biasing operation frequency via a DC voltage will replace banks into a single highly tunable RF filter. Ferroelectric materials are ideal candidates to be used in the RF filters. Good tunability, significantly low dielectric loss and room temperature functionality, as well as fast response, are among the reasons to choose ferroelectric materials.

Coupling multiple RF filters is mostly performed through electric coupling. However, in the case of electric coupling RF filters, a lot of energy leakage occurs when the power is conveyed from one resonator to another. This energy leakage is translated into high insertion in-band losses. Bandwidth in electric coupling is also smaller due to pole-zero characteristic of the transfer function. Acoustically coupled RF filters, however, can cure this drawback.

Realization of high-performance RF filters within a monolithic structure has been intriguing in acoustic device community as it reduces over foot-print of the filter, eliminates various fabrication, packaging and reliability challenges, and reduces routing parasitic inherent to electrically coupled acoustic filters (such as Bulk Acoustic Wave (BAW), ladder, lattice, and/or the like). While the idea of acoustic coupling of two resonance modes within a single structure promises realization of a monolithic filter, achieving comparable performance with electrically coupled counterparts have been challenging. Specifically, acoustically coupled filters suffer from lower bandwidth and larger insertion loss; both of which resulted from partial electrode-coverage inherent to the interdigital transducer (IDT) design of the two-port acoustically coupled filter. In order to overcome these disadvantages, the present application uses a ferroelectric material in an acoustically coupled RF filter.

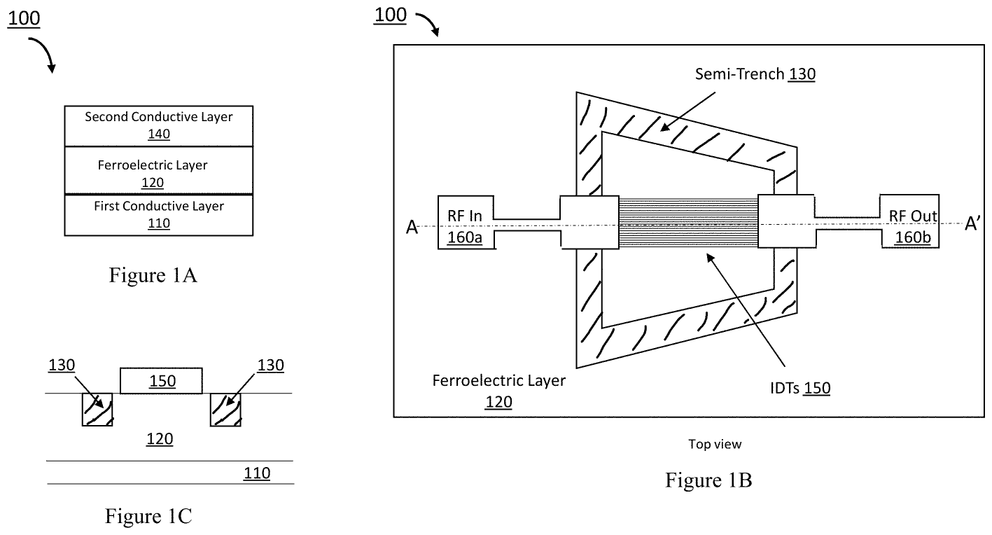

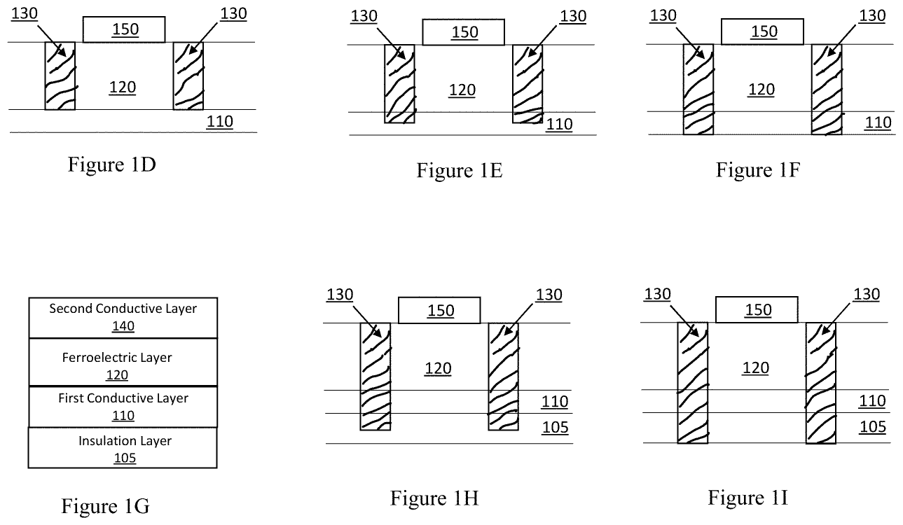

FIGS. 1A-1I are different views of an exemplary acoustically coupled RF filter system 100, in accordance with some embodiments. FIG. 1A and FIG. 1G illustrates different layers of the acoustically coupled RF filter system 100, according to some embodiments. FIG. 1B illustrates a top view of the acoustically coupled RF filter system 100, according to some embodiments. FIG. 1C is a cross-sectional view of acoustically coupled RF filter system 100 shown in FIG. 1B when cut along lines AA′ near the center, according to some embodiments. FIG. 1D-1F and FIG. 1H-1I are possible cross-sectional views of acoustically coupled RF filter system 100 shown in FIG. 1B when cut along lines AA′ near the center, according to some other embodiments. In some embodiments, the acoustically coupled RF filter system 100 comprises a first conductive layer 110, the ferroelectric layer 120, a second conductive layer 140 and a plurality of Interdigital Transducers (IDTs) 150. In some embodiments, the acoustically coupled RF filter system 100 also comprises an insulation layer 105, as shown in FIG. 1G.

In some embodiments, the ferroelectric layer 120 is positioned above the first conductive layer 110. The ferroelectric layer 120 may be sputtered over the first conductive layer 110. In some embodiments, the first conductive layer 110 is positioned above the insulation layer 105. In some embodiments, the ferroelectric layer 120 comprises a semi-trench (or a trench), e.g., the semi-trench 130. In some embodiments, the semi-trench 130 is formed in the ferroelectric layer 120. In some embodiments, the semi-trench 130 extends fully through the ferroelectric layer 120. In some embodiments, the semi-trench 130 extends fully through the ferroelectric layer 120 and partly into the first conductive layer 110. In some embodiments, the semi-trench 130 extends fully through the ferroelectric layer 120 and the first conductive layer 110. In some embodiments, the semi-trench 130 extends fully through the ferroelectric layer 120 and the first conductive layer 110, and partly into the insulation layer 105. In some embodiments, the semi-trench 130 extends fully through the stack of the ferroelectric layer 120, the first conductive layer 110, and the insulation layer 105. In some embodiments, the semi-trench 130 forms a trapezoid-shape region in the ferroelectric layer 120. In some embodiments, the second conductive layer 140 is positioned above the ferroelectric layer 120. In some embodiments, the plurality of IDTs 150 is patterned on the second conductive layer 140. The plurality of IDTs 150 may comprise at least two sets of IDTs. Each set of IDTs may comprise about 10 IDT fingers. In some embodiments, the plurality of IDTs 150 has a pitch of about 5 micrometers.

In some embodiments, the plurality of IDTs 150 forms an input, e.g., RF In 160a, and an output, e.g., RF Out 160b, for the acoustically coupled RF filter system 100. In some embodiments, the insulation layer 105 comprises an insulation material. In some embodiments, the insulation layer 105 comprises silicon (Si). In some embodiments, the first conductive layer 110 comprises a same material as the second conductive layer 140. In some embodiments, one or more of the first conductive layer 110 or the second conductive layer 140 comprises a metal. In some embodiments, one or more of the first conductive layer 110 or the second conductive layer 140 comprises Molybdenum (Mo). In some embodiments, the first conductive layer 110 and the second conductive layer 140 comprise Molybdenum (Mo). In some embodiments, one or more of the first conductive layer 110 or the second conductive layer 140 each has a thickness of about 100 nanometers.

FIG. 1J is an expanded view of IDT 300 of an acoustically coupled RF filter, in accordance with another exemplary embodiments of the present invention. It is understood that FIG. 1J does not show the remaining elements (e.g., trench) of the acoustically coupled RF filter. IDT 300 is shown as including 8 exemplary interdigitated fingers (also referred to herein as fingers) 200₁, 200₂. . . 200₇, 200₈. As is seen, finger 200₂ is disposed between fingers 200₁ and 200₃; finger 200₃ is disposed between fingers 200₂ and 200₄, and the liken.

Fingers 200₁ and 200₃ are shown as being coupled to one another to form a first electrode of the RF filter. Fingers 200₂ and 200₄ are shown as being coupled to one another to form a second electrode of the RF filter. Fingers 200₅ and 200₇ are shown as being coupled to one another to form a third electrode of the RF filter. Fingers 200₆ and 200₈ are shown as being coupled to one another to form a fourth electrode of the RF filter. To operate the filter, a first voltage is applied across the first and second electrodes, and a second voltage is applied across the third and fourth electrodes. The first and second voltage may be different from one another.

Although not shown, it is understood that in other embodiments, a different arrangement of the fingers may be used to form the electrodes. For example, in some embodiments, fingers 200₁ and 200₇ may be a part of the same conductive trace to form a first electrode; fingers 200₂ and 200₈ may be a part of another conductive trace to form a second electrode, and the like. It is also understood that embodiments of the present invention are not limited by the number of fingers, number of electrodes formed using the fingers, and the number/level of voltages applied to the IDT of an acoustically coupled RF filter.

In some embodiments, to overcome the above-mentioned problems with the acoustically coupled RF filters, the ferroelectric layer 120 comprises aluminum-scandium-nitride films (Al₁₋ₓScₓN). The Al₁₋ₓScₓN provides significantly higher electromechanical coupling compared to its aluminum-nitride (AlN) counterparts. Furthermore, Al₁₋ₓScₓN becomes ferroelectric when Sc-content (e.g., x) exceeds 27%. This ferroelectric property can be utilized for agile reconfiguration of the acoustically coupled RF filter system 100 using nonlinear electro-strictive effect. In some embodiments, the ferroelectric layer 120 comprises aluminum-scandium-nitride films Al₁₋ₓScₓN where x is at least 0.27. In some embodiments, the ferroelectric layer 120 has a thickness of about 1 micrometer.

The large electromechanical coupling of the Al₁₋ₓScₓN film when x >0.27, leads to large bandwidths. As a non-limiting example, in some embodiments, the Al₁₋ₓScₓN film possesses a bandwidth about 3-5 times larger than that of its acoustically coupled AlN counterparts. Furthermore, disclosed acoustically coupled RF filter system 100 uses ferroelectricity in Al₁₋ₓScₓN films (x >27%) for large bandwidth tuning of the filter. The architecture of the acoustically coupled filter provides superior characteristics compared to conventional electrically coupled filters (e.g., lattice, ladder, and/or the like) comprising lithographical bandwidth definition through proper IDT patterning, and realization of the filter within a single and/or monolithic structure. The thickness of each of the multiple layers in the acoustically coupled RF filter system 100, the depth and the shape of the semi-trench (or trench), and the number of fingers and the pitch of the plurality of IDTs can be adjusted to achieve a required large bandwidth. Besides, the ferroelectric properties of the Al₁₋ₓScₓN film enable the use of nonlinear electro-strictive effect for local tuning of the electromechanical coupling and dielectric constant of the film using a DC bias. This capability directly translates to the reconfiguration of filter bandwidth and center frequency.

In some embodiments, the aluminum scandium nitride films are acoustically engineered to implement 2.3 GHz filters with about −3 dB bandwidths (e.g., BW−3 dB). In some embodiments, the −3 dB bandwidths (or the bandwidths) is demonstrated over a range of about 70 MHz to about 117 MHz. In some embodiments, an insertion loss of about −6 dB is observed. The observed insertion loss is dominated by a routing line resistance, in accordance with some embodiments. In some embodiments, bandwidth tuning of about 15 MHz (about 15% of the bandwidth) is achieved through application of a DC voltage of about 60 volts, using a bias-tee. In some embodiments, the acoustically coupled RF filters system 100 enables realization of reconfigurable RF front-end for multi-band wireless systems with extensive compatibility with a wide variety of communication standards used in the 5G communications.

In some embodiments, the semi-trench 130 forms a trapezoid region in the ferroelectric layer 120. The semi-trench 130 may be formed by an etching process. In some embodiments, a chlorine etchant may be used to form the semi-trench 130 in the ferroelectric layer 120. In some embodiments, a depth of the semi-trench 130 is smaller than the thickness of the ferroelectric layer 120, thus, confining the semi-trench 130 in the ferroelectric layer 120. In some embodiments, the first conductive layer 110 and the second conductive layer each has a thickness of about 100 nanometers. In some embodiments, the thickness of the ferroelectric layer 120 is about 1 micrometer and the depth of the semi-trench is about 350 nanometers.

In some embodiments, the Al₁₋ₓScₓN film (x >27%), e.g., the ferroelectric layer 120, is sandwiched between two Mo layers, e.g., between the first conductive layer 110 and the second conductive layer 140. In some embodiments, the plurality of IDTs 150 is patterned on the top Mo layer, e.g., the second conductive layer 140, to define the input and output transduction ports, e.g., RF In 160a and RF Out 160b, of the acoustically coupled RF filter system 100. In some embodiments, a trapezoid geometry with non-parallel edges are patterned through etching semi-trench 130 in the Al₁₋ₓScₓN films.

In some embodiments, the acoustically coupled RF filter system 100 is implemented in reactively sputtered Al_{0.7}Sc_{0.3}N films, e.g., the ferroelectric layer 120. The filters are created by etching semi-trenches, e.g., the semi-trench 130, in Al_{0.7}Sc_{0.3}N, e.g., the ferroelectric layer 120, to define a trapezoid acoustic cavity for efficient energy trapping of two thickness-extensional Lamb modes and create a bandpass filter. In some embodiments, the Al_{0.7}Sc_{0.3}N film, the ferroelectric layer 120, is etched by using a high-power chlorine-based recipe to provide an access to bottom Mo electrode, e.g., the first conductive layer 110.

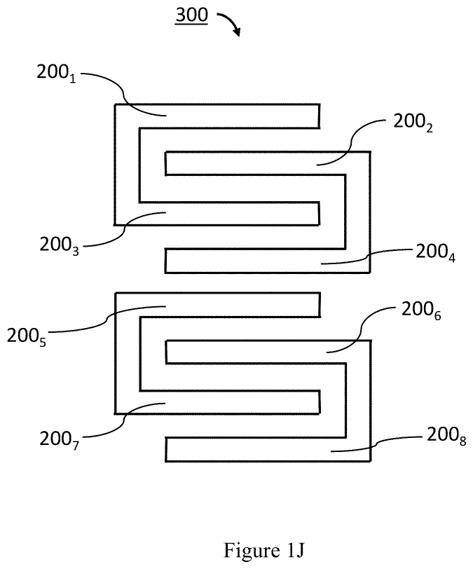

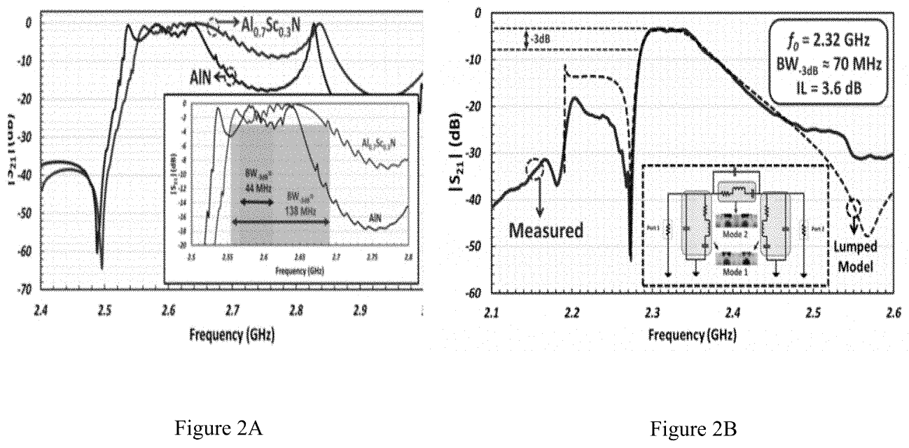

FIG. 2A compares simulated results of different responses of the disclosed acoustically coupled RF filter system, e.g., one with Al_{0.7}Sc_{0.3}N as ferroelectric layer, in accordance with some embodiments, and the other with aluminum nitride (AlN) replacing Al_{0.7}Sc_{0.3}N. Referring to FIG. 2A, the simulation is performed by considering a hypothetical case of similar elastic constants for both films, while reflecting the different piezoelectric coupling coefficient. No material loss is considered to accurately explore the effect of the electromechanical coupling on bandwidth. The inset compares the passband, highlighting significant enhancement of the bandwidth in the disclosed acoustically coupled RF filter system. While the bandwidth of the acoustically coupled filter system should be defined by a pitch size of the plurality of IDTs, the low electromechanical coupling of AlN results in large pass-band ripples which exceed about −3 dB. The simulation confirms that the disclosed acoustically coupled RF filter system with Al_{0.7}Sc_{0.3}N as ferroelectric layer achieves a BW−3 dB of about 3-times compared to the one with AlN.

FIG. 2B demonstrates measured filter response of the disclosed acoustically coupled RF filter system with Al_{0.7}Sc_{0.3}N as ferroelectric layer, showing a BW−3 dB of about 70 MHz. The acoustically coupled RF filter system shows a sharp roll-off at the lower end, which makes it suitable for Rx applications. The inset shows a lumped-element model of the filter, with its response layered on top of the measured response, confirming its accuracy. The measured response is compared with the lumped model that is equivalent to 1.5-stage ladder architecture, e.g., three resonances. This response highlights a promise of the acoustically coupled RF filter system to reduce the footprint.

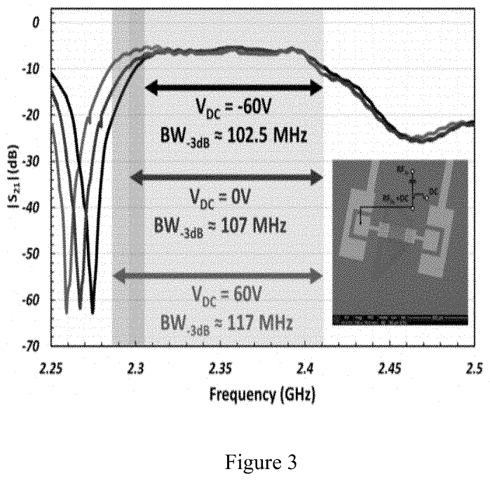

FIG. 3 shows a bandwidth tunability of the acoustically coupled RF filter system, through application of different DC voltages to input IDT set, in accordance with some embodiments. As shown on FIG. 3, a large BW−3 dB tunability of about 15 MHz (e.g., about 15%) is demonstrated using a DC voltage of about 60 V. A reconfigurability of the bandwidth is provided for the ferroelectric effect in Al₁₋ₓScₓN that facilitates local tuning of the dielectric constant and electromechanical coupling by DC fields through the nonlinear electro-strictive effect.

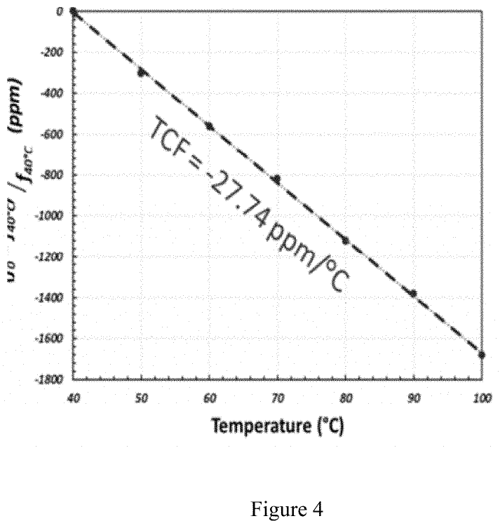

FIG. 4 shows a measured temperature coefficient of frequency (TCF) of the acoustically coupled RF filter system., in accordance to some embodiments. The TCF measurements was performed across a temperature range of 40-100° C. The TCF highlights a value of about 28 ppm/° C.

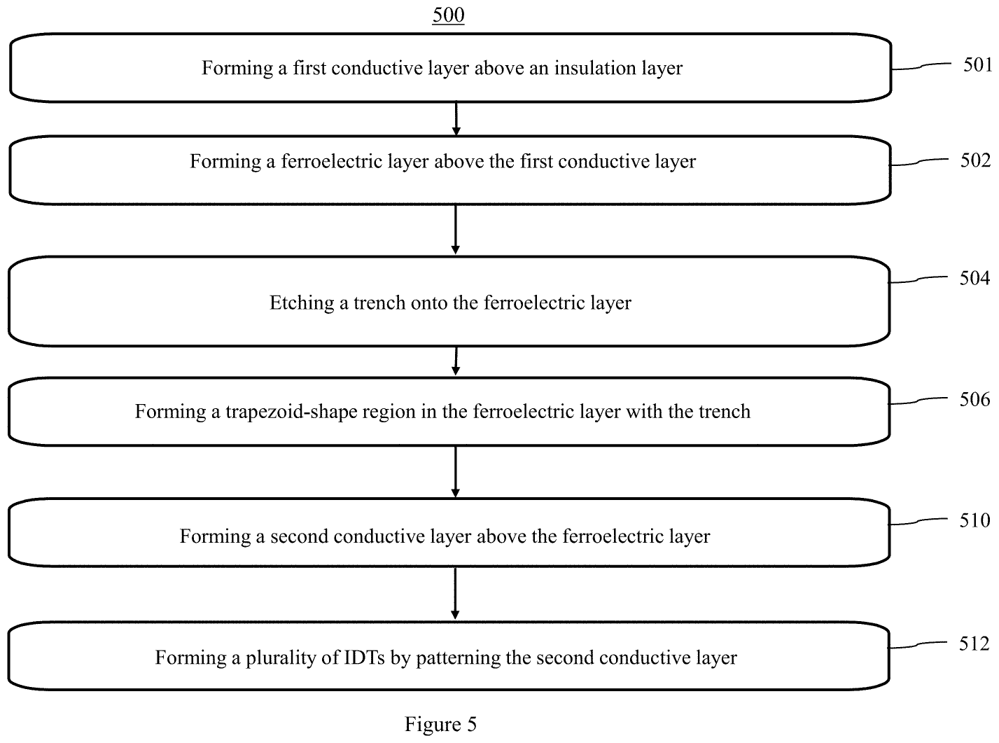

FIG. 5 illustrates a method of fabricating the acoustically coupled RF filter 500, in accordance with some embodiments. In some embodiments, the method 500 comprises forming a first conductive layer above an insultation layer, as represented by block 501. In some embodiments, the method 500 comprises forming a ferroelectric layer above a first conductive layer, as represented by block 502. In some embodiments, a semi-trench (or trench) is formed in the ferroelectric layer. As represented by block 504, in some embodiments, the method 500 comprises etching the semi-trench (or trench) onto the ferroelectric layer. As represented by block 506, the method 500 further comprises forming a trapezoid-shape region in the ferroelectric layer with the semi-trench (or trench). As represented by block 510, in some embodiments, the method 500 comprises forming a second conductive layer above the ferroelectric layer. In some embodiments, the method 500 further comprises forming a plurality of IDTs by patterning the second conductive layer, as represented by block 512. The plurality of IDTs may form an RF filter input and an RF filter output.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best use the invention and various described embodiments with various modifications as are suited to the particular use contemplated.

1. An acoustically coupled radio frequency (RF) filter comprising:
a first conductive layer;
a ferroelectric layer positioned above the first conductive layer, the ferroelectric layer having a trench formed therein; and
a second conductive layer positioned above the ferroelectric layer,
wherein the second conductive layer comprises a plurality of interdigital transducers (IDTs) forming input and output terminals of the filters, and
wherein the ferroelectric layer comprises Al₁₋ₓScₓN, and wherein 0<x<1.

2. The acoustically coupled RF filter of claim 1, wherein the first conductive layer and the second conductive layer comprise a same material.

3. The acoustically coupled RF filter of claim 1, wherein the first conductive layer and the second conductive layer comprise a metal.

4. The acoustically coupled RF filter of claim 1, wherein the first conductive layer and the second conductive layer comprise Molybdenum (Mo).

5. The acoustically coupled RF filter of claim 1, wherein the first conductive layer and the second conductive layer each has a thickness of about 100 nanometers.

6. The acoustically coupled RF filter of claim 1, wherein x is greater than 0.27.

7. The acoustically coupled RF filter of claim 1, wherein the ferroelectric layer has a thickness of about 1 micrometer.

8. The acoustically coupled RF filter of claim 1, wherein the trench is formed in one of the following ways:
extending partly into the ferroelectric layer;
extending fully through the ferroelectric layer;
extending fully through the ferroelectric layer and partly into the first conductive layer; or
extending fully through the ferroelectric layer and the first conductive layer;

9. The acoustically coupled RF filter of claim 1, wherein the trench forms a trapezoid-shape region in the ferroelectric layer.

10. The acoustically coupled RF filter of claim 1, wherein the plurality of IDTs comprises at least two sets of IDTs, wherein each set of IDTs comprises a plurality of IDT fingers.

11. The acoustically coupled RF filter of claim 10, wherein each set of IDTs comprises about 10 fingers.

12. The acoustically coupled RF filter of claim 1, wherein the plurality of IDTs has a pitch of about 5 micrometers.

13. The acoustically coupled RF filter of claim 1, wherein the ferroelectric layer is sputtered over the first conductive layer.

14. The acoustically coupled RF filter of claim 1 further comprising an insulation layer positioned below the first conductive layer.

15. The acoustically coupled RF filter of claim 14, wherein the trench is formed in one of the following ways:
extending partly into the ferroelectric layer;
extending fully through the ferroelectric layer;
extending fully through the ferroelectric layer and partly into the first conductive layer;
extending fully through the ferroelectric layer and the first conductive layer;
extending fully through the ferroelectric layer and the first conductive layer, and partly into the insulation layer; or
extending fully through the ferroelectric layer, the first conductive layer, and the insulation layer.

16. The acoustically coupled RF filter of claim 1, wherein the ferroelectric layer further comprising an access to the first conductive layer.

17. A method of fabricating an acoustically coupled RF filter, comprising:
forming a first conductive layer above an insulation layer;
forming a ferroelectric layer above the first conductive layer;
forming a trench in the ferroelectric layer;
forming a second conductive layer above the ferroelectric layer; and
forming a plurality of interdigital transducers (IDTs) on the second conductive layer, and coupling the IDTs to input and output terminals of the RF filter.

18. The method of claim 17, further comprising etching the trench such that the trench is formed in one of the following ways:
extending partly into the ferroelectric layer;
extending fully through the ferroelectric layer;
extending fully through the ferroelectric layer and partly into the first conductive layer;
extending fully through the ferroelectric layer and the first conductive layer;
extending fully through the ferroelectric layer and the first conductive layer, and partly into the insulation layer; or
extending fully through the ferroelectric layer, the first conductive layer, and the insulation layer.

19. The method of claim 17, wherein the ferroelectric layer is sputtered onto the first conductive layer.

20. The method of claim 17, further comprising forming a trapezoid-shape region in the ferroelectric layer with the trench.
